(19) United States
(12) Patent Application Publication
(10) Pub. No.: US 2006/0267219 A1
(43) Pub. Date: Nov. 30, 2006

(54) Wiring board and semiconductor device

(75) Inventors: Yoshifumi Nakamura, Osaka (JP); Kouichi Nagao, Kyoto (JP); Hiroyuki Imamura, Osaka (JP)

Correspondence Address: HAMRE, SCHUMANN, MUELLER & LARSON P.C., P.O. BOX 2902-0902, MINNEAPOLIS, MN, 55402, US

(73) Assignee: MATSUSHITA ELECTRIC INDUSTRIAL CO., LTD., Kadoma-shi (JP)

(21) Appl. No.: 11/442,185

(22) Filed: May 26, 2006

(30) Foreign Application Priority Data
May 30, 2005 (JP) JP2005-157737

(51) Int. Cl. H01L 23/52

(52) U.S. Cl. 257/784

(57) ABSTRACT

A flexible insulating base, a plurality of conductor wirings provided on the base, and a plurality of bump electrodes that are formed on the plurality of conductor wirings, respectively, are provided. A semiconductor chip having electrode pads is to be mounted by placing the semiconductor chip on the bump electrodes and bonding the electrode pads and the bump electrodes, respectively. The bump electrodes are placed on the conductor wirings, respectively, in edge portions of at least two sides of a chip mounting region in which the semiconductor chip is to be mounted. The conductor wiring corresponding to at least one of the bump electrodes placed in the edge portions of the two sides passes through the chip mounting region so as to be routed via a side different from the side on which the at least one of the bump electrodes is placed, and then led to an outside of the chip mounting region. It is possible to route wirings more freely for leading conductor wirings from bump electrodes placed in an edge portion of a semiconductor chip mounting region to an outside of the chip mounting region.

### BACKGROUND OF THE INVENTION

1. Field of the Invention

The present invention relates to a wiring board configured by providing conductor wirings on a flexible insulating base such as a tape carrier substrate, and a semiconductor device using the same.

2. Description of Related Art

As one type of package modules using a tape carrier substrate, a COF (Chip On Film) package module has been known. The COF package module has a structure in which a semiconductor chip is mounted on a flexible insulating tape carrier substrate and the mounting portion is protected by sealing with a resin. The tape carrier substrate mainly includes an insulating film base and a large number of conductor wirings formed on a surface of the film base. In general, polyimide is used for the film base, and copper is used for the conductor wirings. A metal plating film and a layer of solder resist, which is an insulating resin, are formed on the conductor wirings as needed.

The COF package module mainly is used for packaging a driver for driving a display panel such as a liquid crystal panel. In that case, the conductor wirings on the tape carrier substrate are placed as a first group for forming external terminals for an output signal and a second group for forming external terminals for an input signal. The semiconductor chip is mounted between these groups of conductor wirings. The conductor wirings on the tape carrier substrate and electrode pads on the semiconductor chip are connected via bump electrodes. The conductor wirings in the first group for forming the external terminals for an output signal are connected to electrodes formed in a peripheral portion of the display panel, while the conductor wirings in the second group for forming the external terminals for an input signal are connected to terminals of a motherboard.

An example of the above-described package module using the tape carrier substrate is described in JP 2002-270649 A. The following is a description of a semiconductor device described in this document, with reference to FIG. 7. In FIG. 7, numeral 1 denotes a semiconductor chip. On an upper surface of the semiconductor chip 1, a plurality of electrode pads 2 are formed in each edge portion of upper and lower sides in the figure. A flexible insulating base 3, conductor wirings 4 and bump electrodes 5 form a wiring board, and the semiconductor chip 1 is mounted on this wiring board. This figure shows a state in which the wiring board is placed on the semiconductor chip 1. Accordingly, the conductor wirings 4 and the bump electrodes 5 are located on a lower side of the base 3. However, for the sake of simplicity, the base 3 is indicated by alternate long and short dashed lines, and the other elements can be seen through the base 3.

An inner portion of a chip mounting region on the base 3 in which the semiconductor chip 1 is mounted is provided with a wiring made of an inner lead 14. The inner lead 14 electrically connects the electrode pads 2, which are part of the semiconductor chip 1. In other words, the inner lead 14 is formed in a region opposed to the semiconductor chip 1, and the electrode pads 2 of the semiconductor chip 1 are connected electrically by this inner lead 14 via the bump electrodes 5. This makes it possible to suppress an increase in the number of wirings formed in the semiconductor chip 1 for connecting the electrodes of the semiconductor chip 1.

In the case where the package module using the tape carrier substrate is used in, for example, a liquid crystal display panel, the bump electrodes 5 placed in the edge portion of one of the upper and lower sides in the chip mounting region in FIG. 7 are used for an input signal, while the bump electrodes 5 placed in the edge portion of the other side are used for an output signal, as described above. The conductor wirings 4 corresponding to the bump electrodes 5 for an input signal and those for an output signal are connected to the display panel and the motherboard, respectively. Thus, the location of the electrodes in the semiconductor chip 1 corresponds to an orientation in which such conductor wirings 4 are led out on the wiring board.

However, the wiring density in the semiconductor chip 1 on an input side differs considerably from that on an output side. Therefore, it is desired that the distribution of the bump electrodes 5 for leading out the wirings from the electrode pads 2 of the semiconductor chip 1 be made different from one side to another of the chip mounting region according to the electrode density in the semiconductor chip 1. Nevertheless, considering the placement according to the orientation in which the conductor wirings 4 are led out and an efficient placement distribution of the bump electrodes 5 as described above, it has been difficult to route wirings freely in such a manner as to be adapted for the electrode placement in the semiconductor chip 1.

### SUMMARY OF THE INVENTION

It is an object of the present invention to provide a wiring board that can route wirings more freely for leading conductor wirings from bump electrodes placed in an edge portion of a chip mounting region to an outside of the chip mounting region.

A wiring board according to the present invention includes a flexible insulating base, a plurality of conductor wirings provided on the base, and a plurality of bump electrodes that are formed on the plurality of conductor wirings, respectively. A semiconductor chip having electrode pads is to be mounted by placing the semiconductor chip on the bump electrodes and bonding the electrode pads and the bump electrodes, respectively. The bump electrodes are placed on the conductor wirings, respectively, in edge portions of at least two sides of a chip mounting region in which the semiconductor chip is to be mounted. In order to solve the above-mentioned problem, the conductor wiring corresponding to at least one of the bump electrodes placed in the edge portions of the two sides passes through the chip mounting region so as to be routed via a side different from the side on which the at least one of the bump electrodes is placed, and then led to an outside of the chip mounting region.

A semiconductor device according to the present invention includes a wiring board including a flexible insulating base, a plurality of conductor wirings provided on the base and a plurality of bump electrodes that are formed on the plurality of conductor wirings, respectively, and a semiconductor chip mounted by being placed on the wiring board and bonding electrode pads to the bump electrodes, respectively. The bump electrodes are placed on the conductor wirings, respectively, in edge portions of at least two sides of a chip mounting region in which the semiconductor chip is mounted. The conductor wiring corresponding to at least one of the bump electrodes placed in the edge portions of the two sides passes through the chip mounting region so as to be routed via a side different from the side on which the at least one of the bump electrodes is placed, and then led to an outside of the chip mounting region.

### BRIEF DESCRIPTION OF THE DRAWINGS

FIG. 1 is a plan view showing a structure of a wiring board according to Embodiment 1 of the present invention.

FIG. 2 is a plan view showing a structure of a wiring board according to Embodiment 2 of the present invention.

FIG. 3 is a plan view showing a structure of a wiring board according to Embodiment 3 of the present invention.

FIG. 4 is a plan view showing another structure of the wiring board according to Embodiment 3 of the present invention.

FIG. 5 is a plan view showing a structure of a wiring board according to Embodiment 4 of the present invention.

FIG. 6 is a sectional view showing a structure of a semiconductor device according to an embodiment of the present invention.

FIG. 7 is a plan view showing a structure of a wiring board in a conventional example.

### DETAILED DESCRIPTION OF THE INVENTION

With the above-described configuration according to the present invention, from the bump electrode placed in the edge portions of the two sides of the chip mounting region, the conductor wiring passes through the chip mounting region, is routed via a side different from the side on which the bump electrode is placed, and then led to an outside of the chip mounting region. Consequently, it becomes possible to reduce an imbalance in the placement density of the conductor wirings due to variation in the electrode distribution in the semiconductor chip, thereby providing efficient wirings freely.

In the wiring board of the present invention, it is preferable that an auxiliary bump electrode is formed on the conductor wiring in an edge portion of the side via which the conductor wiring is routed after passing through the chip mounting region.

Also, the plurality of bump electrodes can be placed in each of edge portions of opposed first and second sides of the chip mounting region, and the conductor wiring corresponding to at least one of the bump electrodes placed in the edge portions of the first and second sides can pass through the chip mounting region, be routed via a third side different from the first and second sides and then led to the outside of the chip mounting region.

Further, the plurality of bump electrodes can be placed in each of edge portions of opposed two sides of the chip mounting region, and the conductor wiring corresponding to at least one of the bump electrodes placed in the edge portions of the two sides can pass through the chip mounting region, be routed via a side opposed to the side on which the at least one of the bump electrodes is placed, and then led to the outside of the chip mounting region.

It also is preferable that an inner bump electrode is placed on the conductor wiring passing through the chip mounting region in an inner region other than edge portions of four sides of the chip mounting region.

Further, it is preferable that a dummy conductor wiring is placed symmetrically with the conductor wiring provided with the bump electrode with respect to a center line of the chip mounting region.

The conductor wirings corresponding to at least two of the bump electrodes can pass through the chip mounting region, be routed via the side of the chip mounting region different from the side on which the at least two of the bump electrodes is placed, and then led to the outside of the chip mounting region.

It is preferable that a ratio of an area occupied by the conductor wirings to the chip mounting region is equal to or larger than 30%.

It also is preferable that the conductor wiring other than the conductor wiring that passes through the chip mounting region and is led to the outside of the chip mounting region has an edge portion located in the chip mounting region, and the bump electrodes are placed so that the edge portion projects beyond the bump electrode.

In the semiconductor device of the present invention, it is preferable that an auxiliary bump electrode is formed on the conductor wiring in an edge portion of the side via which the conductor wiring is routed after passing through the chip mounting region.

The semiconductor device of the present invention may have a configuration in which the auxiliary bump electrode is not connected electrically to the electrode pad.

Also, the semiconductor chip can have the electrode pads at positions opposed to the auxiliary bump electrodes, and an insulating layer can be formed so as to cover an entire surface of at least part of the electrode pads.

Alternatively, the semiconductor chip can have no electrode pad at a position opposed to the auxiliary bump electrode.

Alternatively, the plurality of bump electrodes can be placed in each of edge portions of opposed first and second sides of the chip mounting region, and the conductor wirings corresponding to part of the bump electrodes placed in the edge portion of the first side can pass through the chip mounting region so as to be routed via the second side and then led to the outside of the chip mounting region, and the electrode pads corresponding to the conductor wirings that are led out from the first side via the second side and the conductor wirings that are adjacent to those conductor wirings and led out from the bump electrodes in the edge portion of the second side via the second side can be assigned respectively with electric signals related to signal processing by the semiconductor chip sequentially.

It is preferable that an inner bump electrode is placed on the conductor wiring passing through the chip mounting region in an inner region other than edge portions of four sides of the chip mounting region.

Alternatively, a dummy conductor wiring can be placed symmetrically with the conductor wiring provided with the bump electrode with respect to a center line of the chip mounting region.

The following is a description of embodiments of the present invention, with reference to the accompanying drawings.

### Embodiment 1

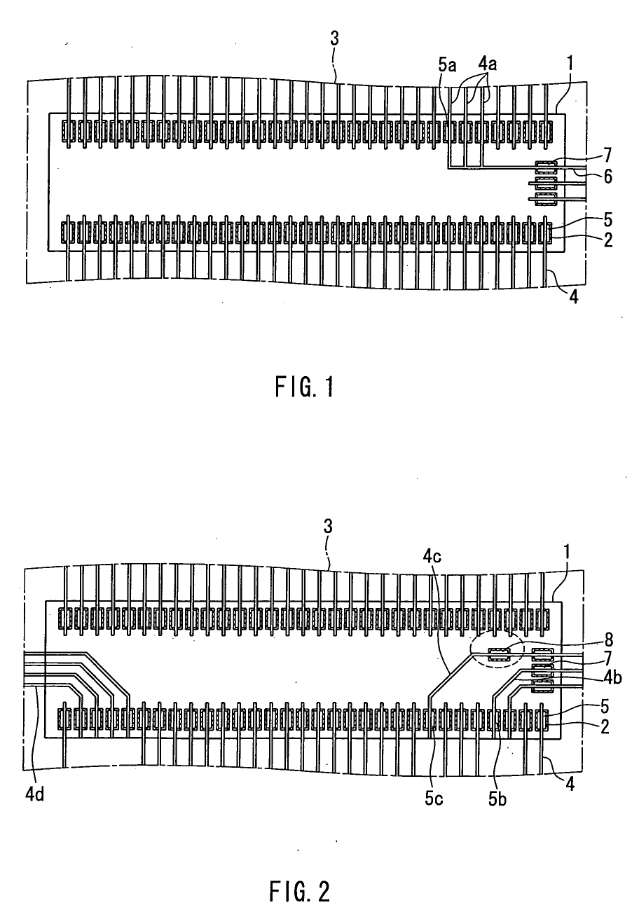

FIG. 1 is a plan view showing a semiconductor device according to Embodiment 1 of the present invention. In FIG. 1, numeral 1 denotes a semiconductor chip. On an upper surface of the semiconductor chip 1, a plurality of electrode pads 2 are formed in each edge portion of upper and lower sides in the figure. A flexible insulating base 3, conductor wirings 4 and bump electrodes 5 form a wiring board, and the semiconductor chip 1 is mounted on this wiring board. This figure shows a state in which the wiring board is placed on the semiconductor chip 1. Accordingly, the conductor wirings 4 and the bump electrodes 5 are located on a lower side of the base 3. However, for the sake of simplicity, the base 3 is indicated by alternate long and short dashed lines, and the other elements can be seen through the base 3. This also applies to the figures for the other embodiments.

A plurality of the conductor wirings 4 are aligned on the base 3 of the wiring board. In the present embodiment, the plurality of conductor wirings 4 are divided into a group on an upper side of the figure and a group on a lower side thereof and spaced apart from each other. Inner edge portions of the conductor wirings 4 in the upper side group and the lower side group respectively are provided with the bump electrodes 5. The base 3 can be formed of, for example, polyimide, and the conductor wirings 4 and the bump electrodes 5 can be formed of, for example, copper. The base 3 formed of polyimide has a thickness of, for example, about 40 μm, and the conductor wirings 4 have a thickness of, for example, about 8 μm. The edge portion of the conductor wiring 4 located in a chip mounting region on which the semiconductor chip 1 is to be mounted projects beyond the bump electrode 5. The bump electrodes 5 are placed in this way, whereby they can be positioned easily with respect to the edge portions of the conductor wirings 4, resulting in a stable bonding state.

The electrode pads 2 of the semiconductor chip 1 and the bump electrodes 5 of the wiring board are placed so as to face each other. In other words, the bump electrodes 5 are placed on individual conductor wirings 4 in the edge portion of two sides in the chip mounting region. The semiconductor chip 1 is mounted by placing the semiconductor chip 1 on the wiring board and bonding the bump electrodes 5 and the electrode pads 2, respectively. Incidentally, although not shown in the figure, a sealing resin is filled between the semiconductor chip 1 and the base 3.

Further, conductor wirings 4a corresponding to three bump electrodes 5a placed in the edge portion on the upper side among the group of the bump electrodes 5 placed in the edge portions of the two sides of the chip mounting region are coupled to one conductor wiring 6 that passes through the chip mounting region so as to be routed via a right side different from the side in which the bump electrodes 5a are placed, and then led to an outside of the chip mounting region. The configuration of leading the conductor wiring 4 to the outside of the chip mounting region in this manner may be applied to one bump electrode 5 or a plurality of the bump electrodes 5. In an edge portion of the right side via which the conductor wiring 6 is routed after passing through the chip mounting region, an auxiliary bump electrode 7 is formed on the conductor wiring 6. The auxiliary bump electrode 7 is bonded to the semiconductor chip by any of the three forms described later.

With the above-described wiring structure in which the conductor wirings 4 are led from the bump electrodes 5 to the outside of the chip mounting region, it becomes possible to reduce an imbalance in the placement density of the conductor wirings due to variation in the electrode distribution in the semiconductor chip, thereby providing efficient wirings freely.

In addition, in the edge portion of the side via which the conductor wiring 6 is routed after passing through the chip mounting region, the auxiliary bump electrode 7 is placed on the conductor wiring 6, whereby the bonding strength of the semiconductor chip 1 with respect to the base 3 becomes uniform. Furthermore, it is possible to achieve an effect of ensuring that the semiconductor chip 1 is spaced away from the conductor wiring 6.

### Embodiment 2

FIG. 2 is a plan view showing a semiconductor device according to Embodiment 2 of the present invention. In the present embodiment, a conductor wiring 4b corresponding to a bump electrode 5b placed in an edge portion of the chip mounting region also passes through the chip mounting region, is routed via the right side and led to the outside of the chip mounting region, similarly to the case of FIG. 1. Also, in the edge portion on the right side via which the conductor wiring 4b is routed after passing through the chip mounting region, an auxiliary bump electrode 7 is formed on the conductor wiring 4b. However, in the present embodiment, one conductor wiring 4b corresponds to one bump electrode 5b and one auxiliary bump electrode 7.

Further, a conductor wiring 4c corresponding to a bump electrode 5c is provided with an inner bump electrode 8 in an inner region other than edge portions of four sides of the chip mounting region. Similarly to the auxiliary bump electrode 7, the inner bump electrode 8 is provided for the purpose of increasing the bonding strength to the semiconductor chip 1 and ensuring that an opposing surface of the semiconductor chip 1 is spaced away from the conductor wiring 4c in the inner region.

It also is possible to provide a configuration in which a conductor wiring 4d provided with no auxiliary bump electrode is led out as illustrated on the left side.

### Embodiment 3

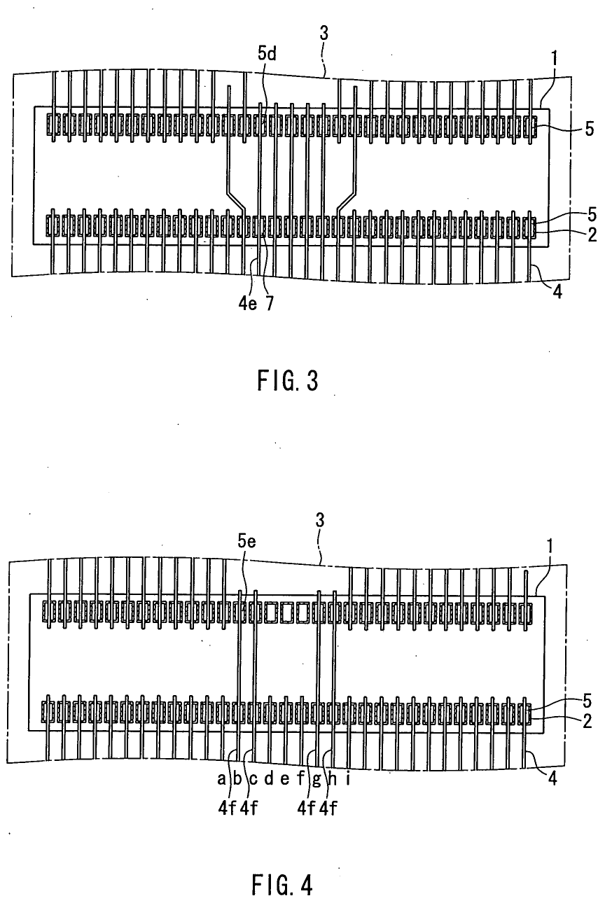

FIG. 3 is a plan view showing an example of a semiconductor device according to Embodiment 3 of the present invention. In the present embodiment, a plurality of bump electrodes 5 are placed in each of edge portions of two opposed sides of the chip mounting region. Conductor wirings 4e corresponding to bump electrodes 5d, which are part of the group of the bump electrodes 5 placed on an upper side among those placed on the two sides, pass through the chip mounting region so as to be routed via a lower side, which is opposite to the side on which these bump electrodes 5d are placed, and then led to an outside of the chip mounting region.

With such routing, in the case of a semiconductor device in which a semiconductor chip used for driving a liquid crystal panel is packaged, for example, it is possible to achieve a considerable effect of alleviating an influence of the variation in the electrode distribution density in a semiconductor chip 1, thereby reducing an imbalance in the placement density of conductor wirings 4. With the placement of the auxiliary bump electrode 7, it also is possible to achieve a considerable effect of improving the bonding strength to the semiconductor chip 1.

FIG. 4 is a plan view showing another example applying the present embodiment. Similarly to the example shown in FIG. 3, a plurality of the bump electrodes 5 are placed in each of edge portions of the opposed upper and lower sides of the chip mounting region. Conductor wirings 4f corresponding to bump electrodes 5e, which are part of those placed in the edge portion on the upper side, pass through the chip mounting region so as to be routed via the lower side and then led to the outside of the chip mounting region. The electrode pads 2 corresponding to the conductor wirings 4f that are led out from the upper side via the lower side and the conductor wirings 4 that are adjacent to the conductor wirings 4f and correspond to the bump electrodes 5 placed in the edge portion of the lower side are assigned respectively with electric signals related to signal processing by the semiconductor chip 1 sequentially as indicated by a to i in the figure.

### Embodiment 4

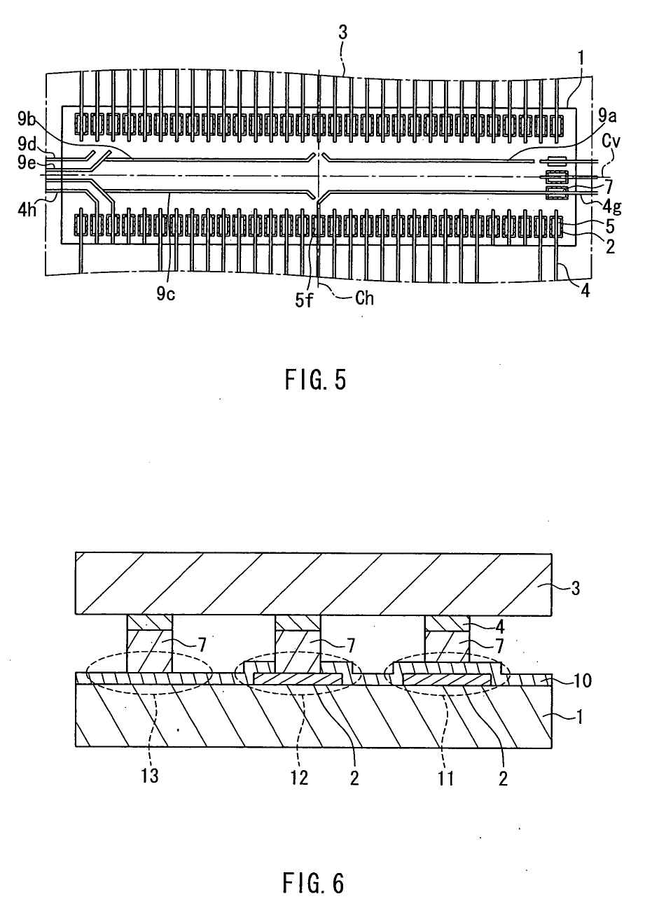

FIG. 5 is a plan view showing a semiconductor device according to Embodiment 4 of the present invention. In FIG. 5, a conductor wiring 4g is led from a bump electrode 5f in a group on a lower side via a right side and to an outside of a chip mounting region, and the conductor wiring 4g and an auxiliary bump electrode 7 serve as elements for routing the wirings more freely similarly to the embodiments described above. Further, though provided with no auxiliary bump electrode, a conductor wiring 4h functions similarly.

On the other hand, dummy conductor wirings 9a to 9e provided with no bump electrode 5 are placed on the left side and in a central portion of the chip mounting region. The dummy conductor wirings 9a to 9e are placed symmetrically with the conductor wirings 4 provided with the bump electrode 5 with respect to center lines Cv and Ch of the chip mounting region.

The dummy conductor wirings 9a to 9e have a function described below. That is to disperse a thermal stress at the time of sealing with a sealing resin, which is caused by a thermal hysteresis when the sealing resin is filled between a semiconductor chip 1 and a base 3, though not shown in the figure. Since the base 3 formed of polyimide has a thickness as small as about 40 μm, it is likely to be distorted by the thermal stress. Thus, when the distribution of the conductor wirings 4 on the base 3 is not uniform, nonuniform distortion occurs, causing problems in the bonding to the bump electrodes 5 and the connection to the display panel and the motherboard. Accordingly, with the dummy conductor wirings 9a to 9e, the wiring distribution on the base 3 is made uniform so as to strike a stress balance, thereby reducing the nonuniform distortion. In this manner, an effect of solving such problems is obtained.

In order to ensure adequate stiffness of the wiring board so as to alleviate the load due to the thermal stress, it is desired to place the conductor wirings 4 and the dummy conductor wirings 9 so that the ratio of an area occupied by the conductor wirings 4 and the dummy conductor wirings 9 to the chip mounting region is equal to or larger than 30%.

### Embodiment 5

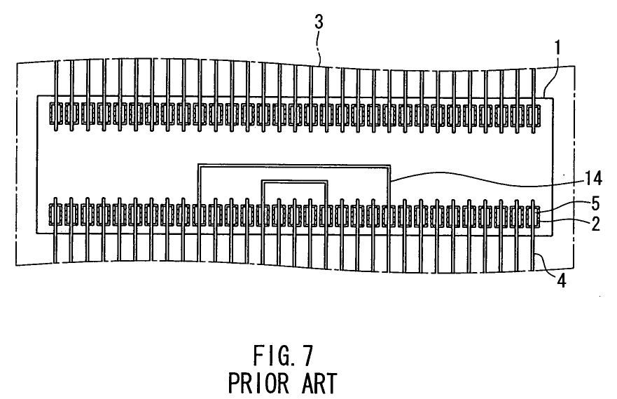

FIG. 6 is a sectional view showing a major portion of a semiconductor device according to Embodiment 5 of the present invention. In FIG. 6, numeral 10 denotes an insulating layer. This figure illustrates three kinds of states 11 to 13 for a bonding relationship between an electrode pad 2 of a semiconductor chip 1 and an auxiliary bump electrode 7.

In the state 11, the electrode pad 2 is provided at a position opposed to the auxiliary bump electrode 7 but is covered with the insulating layer 10. Thus, the auxiliary bump electrode 7 does not contribute to transmission and reception of an electric signal in the semiconductor chip 1. In the state 12, the auxiliary bump electrode 7 and the electrode pad 2 are connected to each other. Thus, the auxiliary bump electrode 7 contributes to the transmission and reception of an electric signal in the semiconductor chip 1. In the state 13, no electrode pad is provided at a position opposed to the auxiliary bump electrode 7.

As described above, since the auxiliary bump electrode 7 is not connected electrically to the electrode pad in the states 11 and 13, it has nothing to do with the transmission and reception of an electric signal. However, placing the auxiliary bump electrode 7 makes it easier to make adjustments such as equalizing the pitch between adjacent bump electrodes so as to reduce the stress on one bump electrode at the time of bonding and also is effective in ensuring that the semiconductor chip 1 is spaced away from the conductor wirings 4 stably.

The invention may be embodied in other forms without departing from the spirit or essential characteristics thereof. The embodiments disclosed in this application are to be considered in all respects as illustrative and not limiting. The scope of the invention is indicated by the appended claims rather than by the foregoing description, and all changes which come within the meaning and range of equivalency of the claims are intended to be embraced therein.

What is claimed is:

1. A wiring board comprising:
a flexible insulating base;
a plurality of conductor wirings provided on the base; and
a plurality of bump electrodes that are formed on the plurality of conductor wirings, respectively;
on which a semiconductor chip having electrode pads is to be mounted by placing the semiconductor chip on the bump electrodes and bonding the electrode pads and the bump electrodes, respectively,
the bump electrodes being placed on the conductor wirings, respectively, in edge portions of at least two sides of a chip mounting region in which the semiconductor chip is to be mounted,
wherein the conductor wiring corresponding to at least one of the bump electrodes placed in the edge portions of the two sides passes through the chip mounting region so as to be routed via a side different from the side on which the at least one of the bump electrodes is placed, and then led to an outside of the chip mounting region.

2. The wiring board according to claim 1, wherein an auxiliary bump electrode is formed on the conductor wiring in an edge portion of the side via which the conductor wiring is routed after passing through the chip mounting region.

3. The wiring board according to claim 1, wherein the plurality of bump electrodes are placed in each of edge portions of opposed first and second sides of the chip mounting region, and the conductor wiring corresponding to at least one of the bump electrodes placed in the edge portions of the first and second sides passes through the chip mounting region so as to be routed via a third side different from the first and second sides and then led to the outside of the chip mounting region.

4. The wiring board according to claim 1, wherein the plurality of bump electrodes are placed in each of edge portions of opposed two sides of the chip mounting region, and the conductor wiring corresponding to at least one of the bump electrodes placed in the edge portions of the two sides passes through the chip mounting region so as to be routed via a side opposed to the side on which the at least one of the bump electrodes is placed, and then led to the outside of the chip mounting region.

5. The wiring board according to claim 1, wherein an inner bump electrode is placed on the conductor wiring passing through the chip mounting region in an inner region other than edge portions of four sides of the chip mounting region.

6. The wiring board according to claim 1, wherein a dummy conductor wiring is placed symmetrically with the conductor wiring provided with the bump electrode with respect to a center line of the chip mounting region.

7. The wiring board according to claim 1, wherein the conductor wirings corresponding to at least two of the bump electrodes pass through the chip mounting region, are routed via the side of the chip mounting region different from the side on which the at least two of the bump electrodes is placed, and then led to the outside of the chip mounting region.

8. The wiring board according to claim 1, wherein a ratio of an area occupied by the conductor wirings to the chip mounting region is equal to or larger than 30%.

9. The wiring board according to claim 1, wherein the conductor wiring other than the conductor wiring that passes through the chip mounting region and is led to the outside of the chip mounting region has an edge portion located in the chip mounting region, and the bump electrodes are placed so that the edge portion projects beyond the bump electrode.

10. A semiconductor device comprising:
a wiring board comprising
a flexible insulating base,
a plurality of conductor wirings provided on the base, and
a plurality of bump electrodes that are formed on the plurality of conductor wirings, respectively; and
a semiconductor chip mounted by being placed on the wiring board and bonding electrode pads to the bump electrodes, respectively;
wherein the bump electrodes are placed on the conductor wirings, respectively, in edge portions of at least two sides of a chip mounting region in which the semiconductor chip is mounted, and
the conductor wiring corresponding to at least one of the bump electrodes placed in the edge portions of the two sides passes through the chip mounting region so as to be routed via a side different from the side on which the at least one of the bump electrodes is placed, and then led to an outside of the chip mounting region.

11. The semiconductor device according to claim 10, wherein an auxiliary bump electrode is formed on the conductor wiring in an edge portion of the side via which the conductor wiring is routed after passing through the chip mounting region.

12. The semiconductor device according to claim 11, wherein the auxiliary bump electrode is not connected electrically to the electrode pad.

13. The semiconductor device according to claim 12, wherein the semiconductor chip has the electrode pads at positions opposed to the auxiliary bump electrodes, and an insulating layer is formed so as to cover an entire surface of at least part of the electrode pads.

14. The semiconductor device according to claim 12, wherein the semiconductor chip has no electrode pad at a position opposed to the auxiliary bump electrode.

15. The semiconductor device according to claim 10, wherein the plurality of bump electrodes are placed in each of edge portions of opposed first and second sides of the chip mounting region, and the conductor wirings corresponding to part of the bump electrodes placed in the edge portion of the first side pass through the chip mounting region so as to be routed via the second side and then led to the outside of the chip mounting region, and
the electrode pads corresponding to the conductor wirings that are led out from the first side via the second side and the conductor wirings that are adjacent to those conductor wirings and led out from the bump electrodes in the edge portion of the second side via the second side are assigned respectively with electric signals related to signal processing by the semiconductor chip sequentially.

16. The semiconductor device according to claim 10, wherein an inner bump electrode is placed on the conductor wiring passing through the chip mounting region in an inner region other than edge portions of four sides of the chip mounting region.

17. The semiconductor device according to claim 10, wherein a dummy conductor wiring is placed symmetrically with the conductor wiring provided with the bump electrode with respect to a center line of the chip mounting region.
